(19) United States
(12) Patent Application Publication
(10) Pub. No.: US 2013/0056261 A1
(43) Pub. Date: Mar. 7, 2013

(54) LEAD FRAME STRIP WITH IMPROVED PACKAGE SEPARABILITY

(71) Applicant: John Paul Tellkamp, Rockwall, TX (US)

(72) Inventor: John Paul Tellkamp, Rockwall, TX (US)

(73) Assignee: TEXAS INSTRUMENTS INCORPORATED, Dallas, TX (US)

(21) Appl. No.: 13/226,117

(22) Filed: Sep. 6, 2011

(51) Int. Cl. H01L 23/495; H01R 43/00

(52) U.S. Cl. 174/536; 29/825

(57) ABSTRACT

A metal lead frame strip is provided for use in manufacturing a packaged electrical device. An engagement portion of the lead frame strip is encapsulated together with the electrical device in a block of encapsulating material to physically secure the lead frame strip to the device package. The device package is later physically separated from the lead frame strip without leaving residual metal exposed on the separated device package.

### FIELD OF THE INVENTION

The invention relates generally to metal lead frame strips that support electrical device packages and, more particularly, to support tabs for lead frame strips.

### BACKGROUND OF THE INVENTION

Metal lead frame strips are commonly used to support electrical device packages during conventional manufacturing steps such as lead trim and form, package symbolization and electrical testing. Each device package is produced by encapsulating an electrical device (which may, e.g., contain one or more constituent components such as integrated circuit devices) in a block of encapsulating material, such as a mold compound applied during a package molding process. The lead frame strip includes support tabs with engagement portions that are encapsulated together with the electrical devices in associated encapsulating blocks. This physically secures the lead frame strip to the device packages. The device packages are physically separated from the lead frame strip after completion of the desired manufacturing step(s).

In a conventional separation procedure, the device packages are forcibly punched out of the lead frame strip. This forcible punching breaks off the support tabs of the lead frame strip at the edges of the encapsulating blocks, leaving residual metal “break” edges exposed on the separated device packages. As discussed in more detail below, this exposed metal is disadvantageous in some circumstances.

It is desirable in view of the foregoing to provide for separating an electrical device package from a metal lead frame strip without leaving residual metal exposed on the separated device package.

### BRIEF DESCRIPTION OF THE DRAWINGS

FIG. 1 diagrammatically illustrates a lead frame strip supporting electrical device packages according to the prior art.

FIG. 2 diagrammatically illustrates a support tab of a prior art lead frame strip.

FIG. 3 diagrammatically illustrates residual metal on a device package of FIG. 1 after separation from the lead frame strip of FIG. 2.

FIG. 4 diagrammatically illustrates an example of a prior art electrical device package that is adversely affected by the residual metal of FIG. 3.

FIG. 5 diagrammatically illustrates a lead frame strip according to example embodiments of the present work.

FIG. 6 diagrammatically illustrates a residual cavity in an electrical device package after separation from the lead frame strip of FIG. 5.

FIG. 7 diagrammatically illustrates a lead frame strip according to further example embodiments of the present work.

FIG. 8 illustrates operations that may be performed using a lead frame strip according to example embodiments of the present work.

### DETAILED DESCRIPTION

FIG. 1 diagrammatically illustrates, in top view, a conventional lead frame strip 11 supporting electrical device packages 12. (Although various structural features are not necessarily shown to scale in FIGS. 1-7, all features are described herein in sufficient detail for an understanding of the present work.) FIG. 1 shows a pair of generally parallel and coplanar elongate metal strip portions 13 of the lead frame strip 11. Metal support tabs 14 extending from the metal strip portions 13 are generally coplanar with and perpendicular to the strip portions. Opposed pairs of the support tabs 14 extend toward one another from their respectively associated strip portions 13 to support associated device packages 12. As shown in FIG. 1, the strip portions 13 have support tabs 14 extending from both opposite sides thereof, such that the lead frame strip 11 can support a rectangular matrix (not shown) of device packages 12. Although not explicitly shown in FIG. 1, the device packages 12 are configured as dual-in-line (DIP) packages, with leads extending from opposite sides 17 of the packages 12.

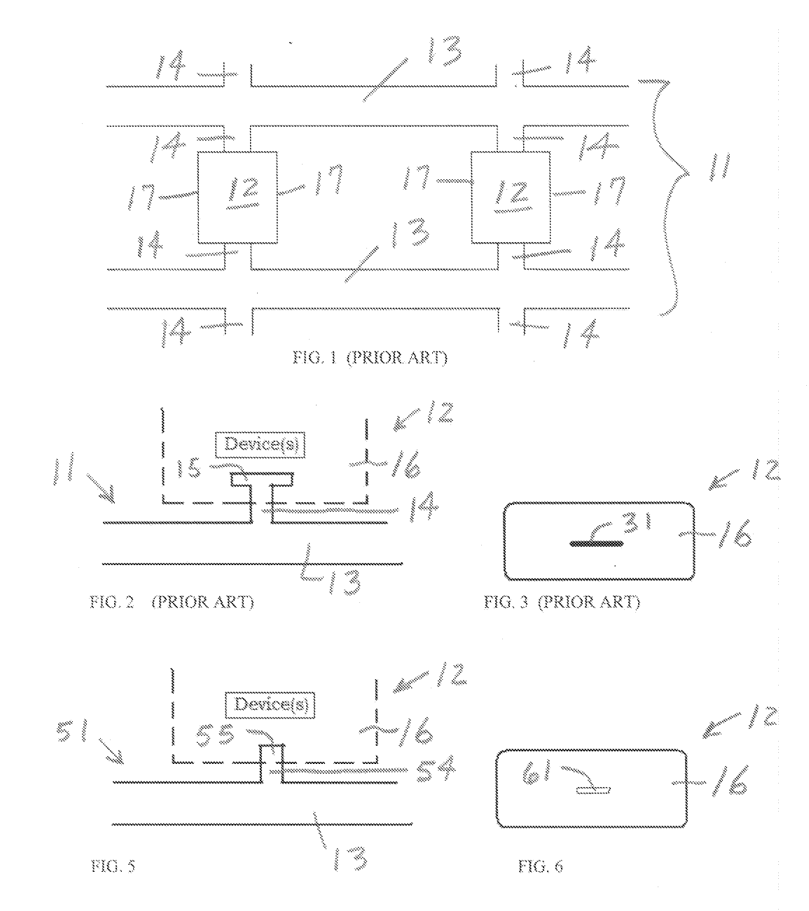

FIG. 2 is a diagrammatic top view that shows in more detail how each support tab 14 of FIG. 1 supports the associated device package 12. Each device package 12 includes an electrical device (which may be composed of, e.g., a plurality of constituent component devices) encapsulated within a block 16 of encapsulating material. Each support tab 14 includes a T-shaped engagement portion 15 that is encapsulated together with the associated device(s) in the associated block 16 of encapsulating material. Thus, the lead frame strip 11 is physically secured to the block 16, and thereby supports the device package 12 for one or more manufacturing operations such as the aforementioned examples.

After completion of the desired manufacturing operation(s), the device packages 12 are forcibly punched out of the lead frame strip 11. This forcible punching operation breaks the metal support tabs 14 at the locations where they emerge from the blocks 16, thereby physically separating the device packages 12 from the lead frame strip 11. After this separation, each T-shaped metal engagement portion 15 remains in the associated device package, with a metal “break” edge exposed at the surface of the encapsulating block 16. FIG. 3 is a diagrammatic side view of one of the device packages 12 after separation from the lead frame strip 11, showing the exposed metal break edge 31.

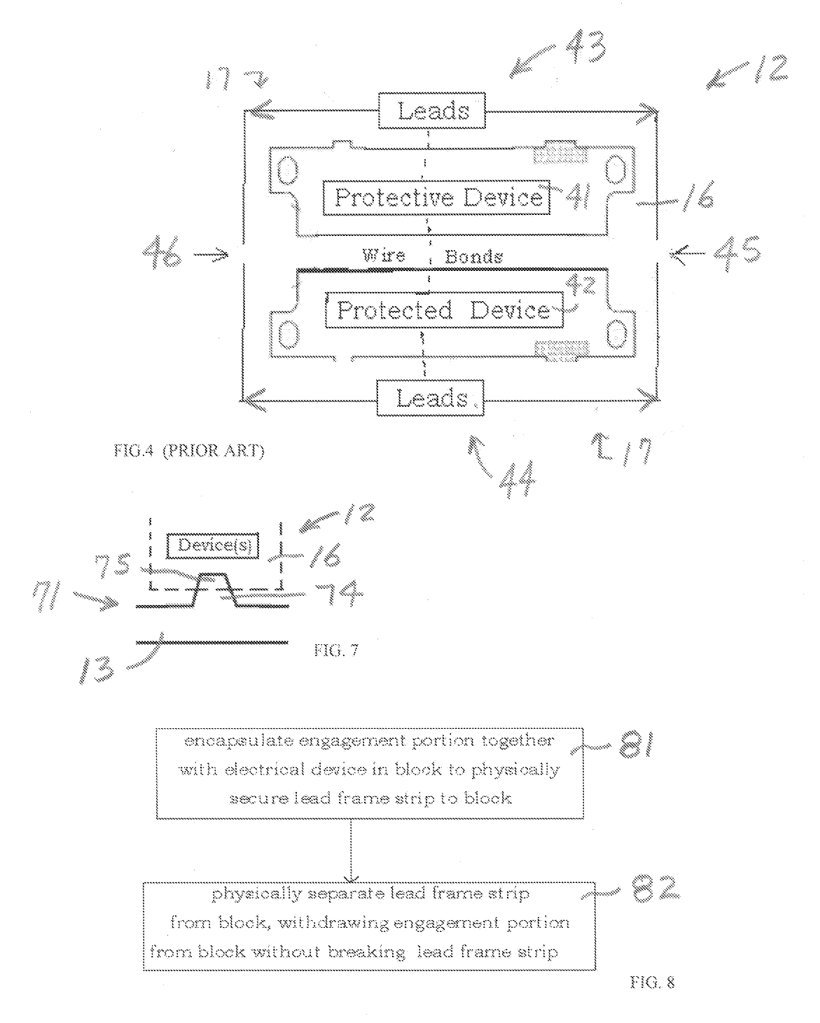

As mentioned above, the exposed metal break edge 31 shown in FIG. 3 is disadvantageous in some circumstances. The following example is provided for illustrative purposes. FIG. 4 is a diagrammatic top view of an example device package 12. The device package 12 of FIG. 4 is an isolation device package including a constituent protective (e.g., integrated circuit) device 41 and a constituent protected (e.g., integrated circuit) device 42 coupled by wire bonds (represented diagrammatically by broken line). The protective device 41 and the protected device 42 are coupled by further wire bonds to line side leads 43 and protected side leads 44, respectively. As shown diagrammatically by arrowheads in FIG. 4, the sets of leads at 43 and 44 are generally distributed along the entire extent of the sides 17 of the device package 12. The protective device 41 on the line side is designed to suppress unwanted interference, for example, voltage spikes. As one example, automotive applications commonly deploy digital data processing circuitry in environments with relatively frequent incidences of voltage spike interference. The protective device 41 suppresses interference and thereby isolates the protected device 42 (e.g., a microprocessor or microcontroller circuit) from interference that may occur on the line side leads 43, permitting the protected device 42 to receive desired data from the leads 43.

The maximum voltage isolation capability of a device package of the type shown in FIG. 4 may be degraded in accordance with a parameter sometimes referred to as “creep distance”. The creep distance corresponds to that part of the distance between the line side leads 43 and the protected side leads 44 that does not contain exposed metal. The longer the creep distance, the higher the maximum voltage isolation capability. It can be seen that the exposed metal break edge 31 of FIG. 3 (instances of which would be located at 45 and 46 in FIG. 4) imposes an upper limit on the achievable creep distance. For instance, one conventional example of the device package 12 of FIG. 4 has a total distance of approximately 4.42 mm between its line side leads 43 and its protected side leads 44. The exposed metal break edges (see 31 in FIG. 3) located at 45 and 46 have a length (in the direction between the leads 43 and 44) of approximately 0.24 mm. Accordingly, in this example, the exposed metal break edges limit the maximum achievable creep distance to 4.42-0.24=4.18 mm.

Example embodiments of the present work provide lead frame strips having support tabs configured to permit them to be withdrawn from the encapsulating blocks when the device package is punched out of the lead frame strip. FIG. 5 is a view similar to FIG. 2, showing a metal lead frame strip 51 according to example embodiments of the present work. The strip portion 13 of FIG. 5 has a generally coplanar support tab 54 extending generally perpendicularly therefrom. The support tab 54 includes an engagement portion 55 that is encapsulated together with the associated electrical device in the associated encapsulating block 16. The engagement portion 55 is configured to permit complete withdrawal thereof from the block 16 when the associated device package 12 is punched out of the lead frame strip 51. In some embodiments, the structure of the lead frame strip 51 shown in FIG. 5 is the same as that of the lead frame strip 11 shown in FIGS. 1 and 2, except the support tabs 14 of FIGS. 1 and 2 are replaced by support tabs 54 such as shown in FIG. 5.

As seen from FIG. 5, in some embodiments, the support tab 54 is configured to correspond dimensionally to the “stem” portion of the T-shaped support tab 14 of FIGS. 1 and 2, that is, the portion of support tab 14 that connects the strip portion 13 to the “cap” portion of the T-shape. Thus, the support tab 54 is configured with a generally rectangular shape that defines three edges, two of which are generally parallel to one another. The two parallel edges extend from the strip portion 13 and terminate at opposite ends of a third edge located at the free end of the tab 54. In the example of FIG. 5, the parallel edges have approximately the same length, and the third edge is generally parallel to the strip portion 13. Because the support tab 54 of FIG. 5 lacks the “cap” of the T-shaped support tab 14 of FIG. 2, the engagement portion 55 that is encapsulated within the block 16 is withdrawn from the block 16 when the device package 12 is forcibly punched out of the lead frame strip 51. The support tab 54 does not break, and there is no residual metal left in the block 16.

FIG. 6 is a side view generally similar to the side view of FIG. 3, showing the device package of FIG. 5 after it has been punched out of the lead frame strip 51. As shown in FIG. 6, the encapsulating block 16 has (at generally the same location as the metal break edge 31 of FIG. 3) a cavity 61 corresponding to the withdrawn engagement portion 55. Accordingly, it can be seen that the use of the lead frame strip 51 with the support tab 54 maximizes the creep distance of a device package such as shown in FIG. 4. Because there is no exposed metal between the line side leads 43 (see also FIG. 4) and the protected side leads 44, the creep distance is the entire distance (4.42 mm in the aforementioned example) between the leads 43 and the leads 44.

Various embodiments use various support tab dimensions. Various embodiments use various configurations adapted in various manners to permit the engagement portion of the support tab to be withdrawn from the encapsulating block when the device package is punched from the lead frame strip. FIG. 7 illustrates a lead frame strip 71 according to example embodiments of the present work. The lead frame strip 71 has a tapered support tab 74 generally coplanar with the strip portion 13 and having opposite edges that converge toward one another as they extend away from the strip portion 13. The converging edges terminate at opposite ends of a third edge located at the free end of the tab 74. In the example of FIG. 7, this third edge is generally parallel to the strip portion 13. The support tab 74 tapers from a first width at the strip portion 13 to a second, narrower width at its free end. In some embodiments, the second, narrower width is the same as the width of the support tab 54 of FIG. 5. In some embodiments, the free end of the support tab 74 is provided at the same distance from the strip portion 13 as is the free end of the support tab 54 of FIG. 5. An engagement portion 75 of the support tab 74 is encapsulated in the block 16. The tapered configuration facilitates withdrawal of the engagement portion 75 from the block 16. In some embodiments, the converging edges of the support tab 74 have approximately equal taper angles. In some embodiments, the lead frame strip 71 has the same structure as the lead frame strip 11 of FIGS. 1 and 2, except the support tabs 14 of FIGS. 1 and 2 are replaced by support tabs 74 such as shown in FIG. 7.

FIG. 8 illustrates operations that may be performed for each lead frame strip support tab according to example embodiments of the present work. At 81, an engagement portion of the support tab is encapsulated together with an electrical device (which may include one or more constituent devices) in an encapsulating block to physically secure the lead frame strip to the encapsulating block. At 82, the lead frame strip is physically separated from the encapsulating block (e.g., by punching the block out of the lead frame strip in some embodiments), withdrawing the engagement portion from the encapsulating block without breaking the lead frame strip.

Although exemplary embodiments of the present work have been described above in detail, this does not limit the scope of the work, which can be practiced in a variety of embodiments.

What is claimed is:

1. A lead frame strip configured to support a plurality of encapsulated electrical devices, comprising:
a strip portion; and
a plurality of tabs extending from said strip portion, each said tab having an engagement portion adapted to be encapsulated together with an associated electrical device in a block of encapsulating material to physically secure said lead frame strip to the block of encapsulating material, each said engagement portion configured for permitting withdrawal of said engagement portion from the associated block of encapsulating material to physically separate said lead frame strip from the block of encapsulating material.

2. The lead frame strip of claim 1, wherein said engagement portions are generally coplanar with said strip portion.

3. The lead frame strip of claim 2, wherein each said engagement portion has a plurality of peripheral edges.

4. The lead frame strip of claim 3, wherein first and second said edges extend away from said strip portion generally parallel to one another and terminate at respective ends of a third said edge.

5. The lead frame strip of claim 4, wherein said first and second edges are approximately equal in length.

6. The lead frame strip of claim 3, wherein first and second said edges extend away from said strip portion and converge toward one another.

7. The lead frame strip of claim 6, wherein said first and second edges terminate at respective ends of a third said edge.

8. A lead frame strip configured to support a plurality of encapsulated electrical devices, comprising:
a strip portion; and
a plurality of tabs extending from said strip portion, each said tab having an engagement portion adapted to be encapsulated together with an associated electrical device in a block of encapsulating material to physically secure said lead frame strip to the block of encapsulating material, each said engagement portion configured for permitting said lead frame strip to be physically separated from the associated block of encapsulating material without breaking said lead frame strip.

9. The lead frame strip of claim 8, wherein said engagement portions are generally coplanar with said strip portion.

10. The lead frame strip of claim 9, wherein each said engagement portion has a plurality of peripheral edges.

11. The lead frame strip of claim 10, wherein first and second said edges extend away from said strip portion generally parallel to one another and terminate at respective ends of a third said edge.

12. The lead frame strip of claim 11, wherein said first and second edges are approximately equal in length.

13. The lead frame strip of claim 10, wherein first and second said edges extend away from said strip portion and converge toward one another.

14. The lead frame strip of claim 13, wherein said first and second edges terminate at respective ends of a third said edge.

15. The lead frame strip of claim 8, wherein the electrical device includes a plurality of constituent component devices.

16. A lead frame strip configured to support a plurality of electrical devices encapsulated in respective blocks of encapsulating material, comprising:
means for permitting said lead frame strip to be physically secured to the blocks of encapsulating material; and
means for permitting said lead frame strip to be physically separated from the blocks of encapsulating material without breaking said lead frame strip.

17. A method of using a lead frame strip, comprising:
encapsulating a portion of the lead frame strip together with an electrical device in a block of encapsulating material to physically secure the lead frame strip to the block of encapsulating material; and
physically separating the lead frame strip from the block of encapsulating material, including withdrawing said portion of the lead frame strip from the block of encapsulating material.

18. The method of claim 17, including supporting the block of encapsulating material on the lead frame strip, and wherein said physically separating includes punching the block of encapsulating material out of the lead frame strip.

19. A method of using a lead frame strip, comprising:
encapsulating a portion of the lead frame strip together with an electrical device in a block of encapsulating material to physically secure the lead frame strip to the block of encapsulating material; and
physically separating the lead frame strip from the block of encapsulating material without breaking the lead frame strip.

20. The method of claim 19, including supporting the block of encapsulating material on the lead frame strip, and wherein said physically separating includes punching the block of encapsulating material out of the lead frame strip.
